(19) United States
(12) Patent Application Publication
(10) Pub. No.: US 2006/0237818 A1
(43) Pub. Date: Oct. 26, 2006

(54) Fuse structure of semiconductor device and method for fabricating same

(75) Inventor: Myoung Sik Chang, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor, Inc., Gyeonggi-do (KR)

(21) Appl. No.: 11/321,629

(22) Filed: Dec. 30, 2005

(30) Foreign Application Priority Data
Apr. 26, 2005 (KR) 10-2005-0034548

(51) Int. Cl. H01L 29/00

(52) U.S. Cl. 257/529

(57) ABSTRACT

Provided a double-wired fuse structure of a semiconductor device and a method for fabricating the same which is not affected electrically by fuse crack. The fuse structure of a semiconductor device comprises a fuse layer formed over a semiconductor substrate wherein a predetermined portion of the fuse layer is cut, contact plugs positioned at the end of the cut fuse layer, a metal layer pattern formed over the fuse layer connecting the contact plugs and blown in fuse blowing, and a fuse box that exposes the metal layer pattern including the connection region of the contact plugs.

### BACKGROUND OF THE INVENTION

1. Field of the Invention

The present invention generally relates to a fuse structure of a semiconductor device and a method for fabricating the same, and more specifically, to a double-wired fuse structure and a method for fabricating the same which is not electrically affected by fuse crack.

2. Description of the Related Art

When even one of fine cells has a defect in fabrication of a semiconductor device, specifically, a memory device, the semiconductor device is not operable as a memory device, so that it is regarded as defective.

However, it is inefficient to discard the whole semiconductor device as a defective even when only a part of cells in the memory has a defect.

The defective cell is replaced with a redundancy cell that is previously prepared in the memory device to repair the whole memory, thereby improving yield.

The repair operation with a redundancy cell is performed by substituting a defective memory cell with a spare memory cell positioned at a spare row and a spare column in each cell array.

More specifically, after a wafer is processed, a test is performed on an internal circuit to select a defective memory cell and replace the corresponding address with an address signal of the spare cell.

When an address signal is inputted to a defective line in the actual usage, a redundant line is replaced.

In one of these program methods, a fuse is burned by a laser beam so as to be disconnected. A wire disconnected by radiation of the laser is referred to as a fuse line, and the disconnected site and its surrounding region are referred to as a fuse box.

FIG. 1 is a cross-sectional diagram illustrating a conventional fuse structure of a semiconductor device and a conventional method for fabricating the same.

Referring to FIG. 1, a first interlayer insulating film 20 is formed on a semiconductor substrate 10.

Then, a fuse layer 30 is formed on the first interlayer insulating film 20.

Thereafter, a second interlayer insulating film 40 is formed on the first interlayer insulating film 20 and the fuse layer 30.

Next, the second interlayer insulating film 40 is etched to form a fuse box 50.

According to the prior art, a crack 60 is generated by stress resulting from a thermal process performed in a subsequent packaging process in a bottom edge of the fuse box. As a result, resistance of a fuse is increased so that the semiconductor device is abnormally operated.

### SUMMARY OF THE INVENTION

Various embodiments are directed at providing a double-wired fuse structure of a semiconductor device and a method for fabricating the same which is not electrically affected by fuse crack, thereby improving yield

According to one embodiment, a fuse structure of a semiconductor device comprises a fuse layer formed over a semiconductor substrate wherein a predetermined portion of the fuse layer is cut, contact plugs positioned at the end of the cut fuse layer, a metal layer pattern formed over the fuse layer connecting the contact plugs and blown in fuse blowing, and a fuse box that exposes the metal layer pattern including the connection region of the contact plugs.

According to one embodiment, a method for fabricating a fuse of a semiconductor device comprises the steps of: (a) forming a first interlayer insulating film on a semiconductor substrate; (b) forming a fuse layer on the first interlayer insulating film; (c) etching a predetermined portion of the fuse layer to cut the fuse layer; (d) forming a second interlayer insulating film on the first interlayer insulating film and the fuse layer; (e) etching the second interlayer insulating film to form a contact holes which exposes the end of the cut fuse layer; (f) forming contact plugs for filling the contact holes; (g) forming a metal layer on the contact plugs and the second interlayer insulating film; and (h) patterning the metal layer to form a metal layer pattern connecting the contact plugs.

### BRIEF DESCRIPTION OF THE DRAWINGS

Other aspects and advantages of the present invention will become apparent upon reading the following detailed description and upon reference to the drawings in which:

FIG. 1 is a cross-sectional diagram illustrating a conventional fuse structure of a semiconductor device and a conventional method for fabricating the same; and

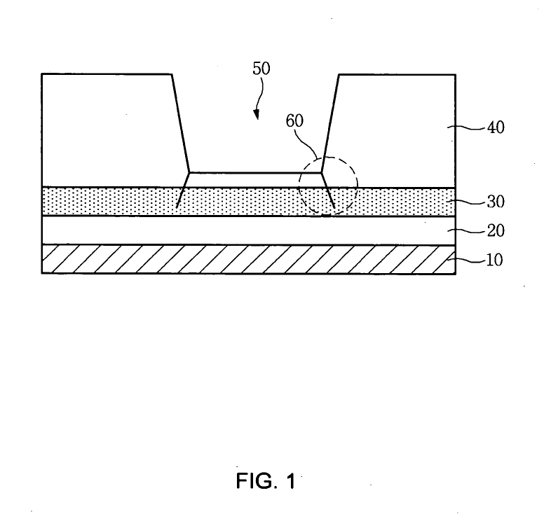

FIG. 2 is a cross-sectional diagram illustrating a fuse structure of a semiconductor device and a method for fabricating the same according to an embodiment of the present invention.

### DETAILED DESCRIPTION OF THE EXAMPLARY EMBODIMENTS

The present invention will be described in detail with reference to the accompanying drawings. Wherever possible, the same reference numbers will be used throughout the drawings to refer to the same or like parts.

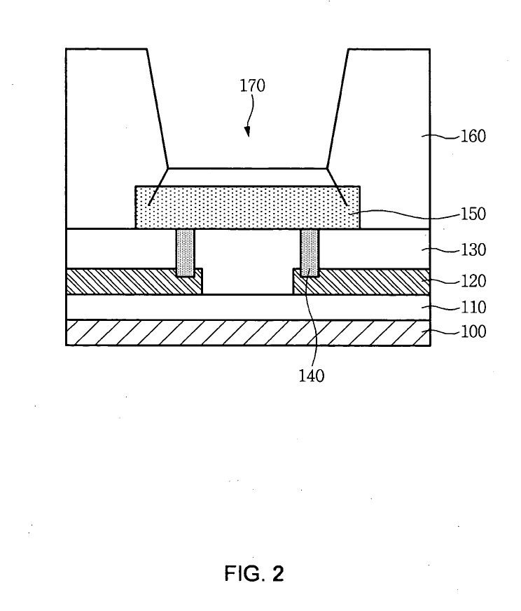

FIG. 2 is a cross-sectional diagram illustrating a fuse structure of a semiconductor device and a method for fabricating the same according to an embodiment of the present invention.

Referring to FIG. 2, a first interlayer insulating film 110 is formed on a semiconductor substrate 100, and a fuse layer 120 is formed on the first interlayer insulating film 110.

A predetermined portion of the fuse layer 120 is cut, and the fuse layer 120 is preferably selected from the group consisting of polysilicon, polycide, TiN, tungsten (W), aluminum (Al) and combinations thereof.

The fuse layer 120 has a fuse that is preferably a plate electrode or a metal wire layer.

Contact plugs 140 are positioned at the end of the cut fuse layer 120. The contact plugs 140 are preferably selected from the group consisting of polysilicon, polycide, TiN, tungsten (W), aluminum (Al) and combinations thereof.

A second interlayer insulating film 130 is formed on the first interlayer insulating film 110 and the fuse layer 120.

A metal layer pattern 150 is formed on the second interlayer insulating film 130 and the contact plugs 140. The metal layer pattern 150 is formed over the fuse layer 120 connecting the contact plugs 140, and blown in fuse blowing.

The metal layer 150 is preferably selected from the group consisting of polysilicon, polycide, TiN, tungsten (W), aluminum (Al) and combinations thereof.

Preferably, the location of the contact plugs 140 and the metal layer 150 is properly adjusted in consideration of location of fuse crack without electric effect even when the fuse is disconnected.

A fuse box 170 that exposes the metal layer pattern 150 including the connection region of the contact plugs 140 is formed on the metal layer pattern 150.

Referring to FIG. 2, a method for fabricating the above-described fuse structure of the semiconductor device is described.

The first interlayer insulating film 110 is formed on the semiconductor substrate 100.

The fuse layer 120 is formed on the first interlayer insulating film 110.

The fuse layer 120 is preferably selected from the group consisting of polysilicon, polycide, TiN, tungsten (W), aluminum (Al) and combinations thereof.

A predetermined portion of the fuse layer 120 is etched to cut the fuse layer 120.

The second interlayer insulating film 130 is formed on the first interlayer insulating film 110 and the fuse layer 120.

The second interlayer insulating film 130 is etched to form contact holes that exposes the end of the cut fuse layer 120.

Then, the contact plugs 140 for filling the contact holes are formed.

The contact plugs 140 are preferably selected from the group consisting of polysilicon, polycide, TiN, tungsten (W), aluminum (Al) and combinations thereof.

A metal layer is formed on the second interlayer insulating film 130 and the contact plugs 140.

The metal layer is patterned to form the metal layer pattern 150 connecting the contact plugs 140.

The metal layer pattern 150 is preferably selected from the group consisting of polysilicon, polycide, TiN, tungsten (W), aluminum (Al) and combinations thereof.

A third interlayer insulating film 160 is formed on the second interlayer insulating film 130 and the metal layer pattern 150.

Then, the third interlayer insulating film 160 is etched to form a fuse box 170.

As described above, a fuse structure of a semiconductor device and a method for fabricating the same according to one embodiment of the present invention have the following effects.

First, a double-wired fuse structure reduces a repair etching target more than that of a single wired fuse structure which employs a plate electrode, thereby increasing productivity and facilitating thickness adjustment of repair remaining oxide on a fuse.

Second, it is possible to use a conventional fuse guardring structure and an upper metal wire layer as a fuse even when the number of metal wire layers is increased.

Third, location of a metal wire layer and contact plugs is properly adjusted, and is not electrically affected even when fuse crack is generated, thereby improving yield loss.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. A fuse structure of a semiconductor device, comprising:
a fuse layer formed over a semiconductor substrate wherein a predetermined portion of the fuse layer is cut;
contact plugs positioned at both ends of the cut fuse layer;
a metal layer pattern formed over the fuse layer connecting the contact plugs; and
a fuse box that exposes the metal layer pattern including the connection region of the contact plugs.

2. The fuse structure according to claim 1, wherein the fuse layer, the contact plugs and the metal layer pattern are individually selected from the group consisting of polysilicon, polycide, TiN, tungsten, aluminum and combinations thereof.

3. A method for fabricating a fuse of a semiconductor device, comprising the steps of:
(a) forming a first interlayer insulating film on a semiconductor substrate;
(b) forming a fuse layer on the first interlayer insulating film;
(c) etching a predetermined portion of the fuse layer to cut the fuse layer;
(d) forming a second interlayer insulating film on the first interlayer insulating film and the fuse layer;
(e) etching the second interlayer insulating film to form contact holes which exposes the end of the cut fuse layer;
(f) forming contact plugs for filling the contact holes;
(g) forming a metal layer on the contact plugs and the second interlayer insulating film; and
(h) patterning the metal layer to form a metal layer pattern connecting the contact plugs.

4. The method according to claim 3, wherein the fuse layer, the contact plugs and the metal layer pattern are individually selected from the group consisting of polysilicon, polycide, TiN, tungsten, aluminum and combinations thereof.
